(19) United States
(12) Patent Application Publication
(10) Pub. No.: US 2025/0210447 A1
(43) Pub. Date: Jun. 26, 2025

(54) Semiconductor Device and Methods of Manufacturing a Semiconductor Device

(71) Applicant: Celanese Mercury Holdings Inc., Wilmington, DE (US)

(72) Inventors: Shufang Yu, Garnet Valley, PA (US); Henry Rosenfeld, Drumore, PA (US); Hsin-cheng Lee, Taoyuan City (TW); Chih-liang Yang, Hsin-Chu County (TW)

(21) Appl. No.: 18/957,958

(22) Filed: Nov. 25, 2024

Related U.S. Application Data
(60) Provisional application No. 63/612,389, filed on Dec. 20, 2023.

(51) Int. Cl. H01L 23/373; H01L 23/00

(52) U.S. Cl. CPC H01L 23/3737; H01L 23/3736; H01L 24/29; H01L 24/32; H01L 24/83; H01L 2224/2929; H01L 2224/29291; H01L 2224/29339; H01L 2224/32245; H01L 2224/83862; H01L 2924/3511

(57) ABSTRACT

A semiconductor device including a semiconductor chip formed from a semiconductive material and a cover formed from a conductive material is provided. The semiconductor chip and cover are bonded with a thermal interface material composition that includes metal particles dispersed in a resin or resin blend and a silane-based adhesion promoter. The TIM composition may also include a rubber and a curing agent. Methods of making semiconductor devices are also provided.

### RELATED APPLICATION

The present application is based upon and claims priority to U.S. Provisional Patent Application Ser. No. 63/612,389, having a filing date of Dec. 20, 2023, which is incorporated herein by reference.

### BACKGROUND OF THE DISCLOSURE

Electronic devices, including those containing semiconductors, can generate a significant amount of heat during operation. In order to cool semiconductor devices, heat sinks, cold plates, or other heat spreaders are affixed to the device. Heat generated during operation of the device is transferred from the semiconductor to the heat sink where the heat is dissipated. In order to maximize heat transfer between the semiconductor device and the heat sink, thermally conductive interface materials are used. The thermal interface materials (TIM) facilitate thermal connectivity between the semiconductor device and the heat sink to provide more intimate contact between the parts and facilitate heat transfer.

Commonly, paste-like thermally conductive materials (e.g., silicone grease) or film-like thermally conductive materials can be used. However, utilization of such grease and paste-like materials are typically applied in a liquid or semi-solid state, which can make their application messy. Additionally, such materials can bleed or be squeezed out and bleed onto unwanted areas. Film-like materials include additional film forming agents that can increase manufacturing costs. Additionally, for certain applications, the TIM material should exhibit sufficient adhesion to bond components together. Many TIM materials do not provide sufficient adhesion between component parts.

As such, a need exists for improved TIMs having low resistivity and excellent adhesion, and high thermal conductivity.

### SUMMARY OF THE DISCLOSURE

Aspects and advantages of embodiments of the present disclosure will be set forth in part in the following description, or may be learned from the description, or may be learned through practice of the embodiments.

In one aspect, a semiconductor device including a semiconductor chip formed from a semiconductive material and a cover formed from a conductive material is provided. The semiconductor chip and cover are bonded with a thermal interface material composition that includes metal particles dispersed in a resin and a silane-based adhesion promoter. The TIM composition may also include a rubber and a curing agent. Advantageously, the composition can be solventless.

In another aspect, disclosed is a method for making a semiconductor device. The method includes disposing a thermal interface material composition including a conductive material comprising metal particles dispersed in a resin and a silane-based adhesion promoter on a cover formed from a conductive material. The method includes placing a semiconductor chip formed from a semiconductive material on the thermal interface material composition forming a component assembly and curing the component assembly to bond the cover and the semiconductor chip.

Other features and aspects of the present disclosure are set forth in greater detail below.

### BRIEF DESCRIPTION OF THE FIGURES

A full and enabling disclosure of the present disclosure, including the best mode thereof, directed to one of ordinary skill in the art, is set forth more particularly in the remainder of the specification, which makes reference to the appended figures in which:

FIG. 1 is a cross-sectional view of a component assembly according to one embodiment of the present disclosure;

FIG. 2 is a cross-sectional view of a component assembly component according to one embodiment of the present disclosure; and

FIG. 3 is a flow chart of an example method of forming a component assembly according to one embodiment of the present disclosure. In the graph

Repeat use of references characters in the present specification and drawing is intended to represent same or analogous features or elements of the disclosure.

### DETAILED DESCRIPTION

It is to be understood by one of ordinary skill in the art that the present discussion is a description of exemplary embodiments only, and is not intended as limiting the broader aspects of the present disclosure.

Generally speaking, the present disclosure is directed to a semiconductor device including a semiconductor chip formed from a semiconductor material (e.g., silicon) and a cover formed from a conductive material (e.g., metal). The semiconductor chip and cover are bonded with a thermal interface material (TIM) composition having low resistivity, good thermal conductivity, and good adhesion to the respective parts. The TIM composition includes metal particles dispersed within a resin and a silane-based adhesion promoter. The TIM composition can also include rubber and a curing agent. The TIM composition can be free from additional solvents (e.g., can be solventless) and, once cured, exhibits good adhesion and provides effective thermal conductivity between the joined components.

Further, the present disclosure also provides a method for making a semiconductor device. The method includes disposing the TIM composition on a cover formed from a conductive material. The TIM composition includes conductive material (e.g., metal particles) dispersed in a resin and a silane-based adhesion promoter. The TIM composition may also include a rubber and a curing agent. The method includes placing a semiconductor chip formed from a semiconductive material (e.g., silicon) on the TIM composition forming a component assembly (e.g., semiconductor device). The component assembly is then cured to bond the semiconductor chip and the cover. The TIM composition facilitates thermal transfer between the semiconductor chip and the cover and can bond the semiconductor chip and cover.

Through selective control over the particular nature of the specific concentration of the components of the TIM composition, the present inventors have discovered that the resulting TIM composition exhibits low resistivity and good thermal conductivity while maintaining proper adhesion between the semiconductor chip and cover during multiple product operation cycles. Further, the TIM composition exhibits good bulk resistivity while maintaining good interfacial bonding between the surfaces of the component parts to facilitate heat transfer.

Various embodiments of the present disclosure will now be described in more detail.

### I. TIM Composition

a. Conductive Material

The TIM composition includes a conductive material. The conductive material of the present disclosure is not subject to any special limitation as long as it does not have an adverse effect on the technical effect of the present disclosure. The conductive material can include conductive materials with an electrical conductivity of about 7.00×10⁶ Siemens(S)/m or higher at 293 Kelvin in an embodiment, about 8.50×10⁶ S/m or higher at 293 Kelvin in another embodiment, about 1.00×10⁷ S/m or higher at 293 Kelvin in another embodiment, or about 4.00×10⁷ S/m or higher at 293 Kelvin in another embodiment.

The conductive material can include metal particles including aluminum (Al, 3.64×10⁷ S/m), nickel (Ni, 1.45×10⁷ S/m), copper (Cu, 5.81×10⁷ S/m), silver (Ag, 6.17×10⁷ S/m), gold (Au, 4.17×10⁷ S/m), molybdenum (Mo, 2.10×10⁷ S/m), magnesium (Mg, 2.30×10⁷ S/m), tungsten (W, 1.82×10⁷ S/m), cobalt (Co, 1.46×10⁷ S/m), zinc (Zn, 1.64×10⁷ S/m), platinum (Pt, 9.43×10⁶ S/m), palladium (Pd, 9.5×10⁶ S/m), indium (In, 1.20×10⁷ S/m), alloys thereof, and mixtures thereof.

In embodiments, the conductive material can be silver. In the case of using silver as the conductive material, it can be in the form of silver metal, silver-coated composites, and/or the mixture thereof. Suitable silver-coated composites include a layer of silver coated on the surface of a silver-based alloy or other metal material.

The conductive material can be in the form of powder (for example, spherical shape, flakes, irregular form and/or the mixture thereof). Specifically, in an embodiment the metal powder includes metal particles that are in the form of flakes. As used herein a “flake” particle is one having a high diameter-to-thickness aspect ratio. As used herein “aspect ratio” is used to define the proportional relationship between the particle's diameter and thickness. For instance, a flake particle can have an aspect ratio (e.g., diameter to thickness) of about 2:1 to about 10:1, such as about 3:1 to 9:1, such as about 4:1 to about 8:1, such as about 5:1 to about 7:1. The average particle diameter (D50) of the metal particles can range from about 1 μm to about 5 μm, such as from about 1 μm to about 4 μm, such as from about 2 μm to about 3 μm. The particle diameter (D50) can be measured by laser diffraction scattering method with Microtrac model S-3500. As used herein “D50” means that 50% of the particles are smaller than the recited size and 50% of the particles are larger than the recited size. Mixtures of metals having different average particle sizes, particle size distributions or shapes, etc. can also be employed. In one embodiment of the present disclosure, the metal particles are present in amounts ranging from about 70 wt. % to about 99 wt. %, such as from about 85 wt. % to about 95 wt. %, such as from about 75 wt. % to about 95 wt. % based on the total weight of the composition.

In certain embodiments, the conductive material can also include submicron particles in addition to the micron-sized particles disclosed hereinabove. For instance, in embodiments, the composition can include submicron metal particles having a particle diameter (D50) of from about 0.1 μm to about 0.7 μm, such as from about 0.2 μm to about 0.6 μm, such as from about 0.3 μm to about 0.5 μm. The submicron metal particles can be included in amounts ranging from about 0.1 wt. % to about 10 wt. %, such as from about 0.5 wt. % to about 9 wt. %, such as from about 1 wt. % to about 8 wt. %, such as from about 2 wt. % to about 7 wt. %, such as from about 3 wt. % to about 6 wt. % based on the total weight of the composition. Notably, in embodiments, the submicron metal particles comprise silver. The submicron metal particles can be spherical or flake particles. In an embodiment, the submicron particles are flake particles. The submicron metal particles can improve or increase packing density of the conductive material dispersed within the composition and can further increase conductivity of the adhesive composition.

Optionally, the metal particles disclosed herein, including the submicron metal particles, can include a coating thereon. For instance, the metal particles can be coated with a metal coating, typically, a different metal from that used to form the metal particles themselves. For instance, the metal particles can be formed from silver and can include a coating disposed thereon formed from one or more alkali metals, such as aluminum, gallium, indium, tin, thallium, lead, bismuth, polonium, astatine, or combinations thereof. In one embodiment, the metal particles are silver particles coated with indium. In other embodiments, the particles can be coated with a coating containing one or more post-transition metals.

The metal particles can be coated with any suitable surfactant. In embodiments, the metal particles are coated with a lipid, such as a fatty acid. The fatty acids can include free fatty acids, fatty acid salts, or fatty acid esters that can be branched, unbranched, saturated or unsaturated. Suitable fatty acids include, but are not limited to, oleic acid, stearic acid, lauric acid, caprylic acid, capric acid, myristic acid, palmitic acid, arachidic acid, behenic acid, lignoceric acid, cerotic acid, and combinations thereof. In other embodiments, the metal particles can be coated with an anionic surfactant. Suitable anionic surfactants include sodium lauryl sulfate, sodium laureth sulfate, ammonium lauryl sulfate, ammonium laureth sulfate, sodium stearate, potassium cocoate, and combinations thereof. The coatings disclosed herein can be disposed on the surface of the metal particles by any means known in the art.

The coating can be present in amounts ranging from about 1 wt. % to about 15 wt. %, such as from about 2 wt. % to about 10 wt. %, such as from about 2 wt. % to about 5 wt. % based on the total weight of the metal particles.

b. Resin

The resin of the present disclosure can include any suitable resin including thermoplastic resins, thermoset resins, and combinations thereof. For instance, in embodiments the resin can include acrylic resins (e.g., vinyl ether acrylate resins, cyanoacrylate resins, polymethyl methacrylate etc.); polyepoxide resins; polyamides; poly(vinyl alcohol) PVA; polyethylene; polypropylene; polystyrene; poly(vinyl chloride); polyurethanes; polysiloxanes; acetal copolymers (e.g., polyoxymethylene, ethyl vinyl acetate); and combinations thereof.

In embodiments, the resin includes a polyepoxide resin. The polyepoxide resin useful in the practice of the present disclosure is suitably a compound which possesses more than one 1,2-epoxy group. In general, the polyepoxide resin is a saturated or unsaturated aliphatic, cycloaliphatic, aromatic or heterocyclic compound which possesses more than one 1,2-epoxy group. The polyepoxide resin can be substituted with one or more substituents such as lower alkyls and halogens. Such polyepoxide resins are well known in the art. Illustrative polyepoxide compounds useful in the practice of the present disclosure are described in the Handbook of Epoxy Resins by H. E. Lee and K. Neville published in 1967 by McGraw-Hill, New York and U.S. Pat. No. 4,066,628, incorporated herein by reference. The preparation of epoxy resin compounds suitable for use in the present disclosure is described, for example, in Kirk-Othmer, Encyclopedia of Chemical Technology, 3rd Edition, Vol. 9, pages 267-289, which is incorporated herein by reference. Other suitable epoxy resins suitable for use in the TIM composition of the present disclosure are disclosed, for example, in U.S. Pat. Nos. 3,018,262; 7,163,973; 6,887,574; 6,632,893; 6,242,083; 7,037,958; 6,572,971; 6,153,719; 5,137,990; 6,451,898; 8,048,819; 7,655,174; 7,923,073; and 5,405,688; all of which are incorporated herein by reference.

Polyepoxide resins which can be used in the TIM composition are polyepoxides having the following general formula:

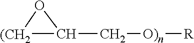

wherein R is substituted or unsubstituted aromatic, aliphatic, cycloaliphatic or heterocyclic polyvalent group and n had an average value of from 1 to less than about 8.

Examples of known epoxy resins that may be used in the present disclosure, include for example, the diglycidyl ethers of resorcinol, catechol, hydroquinone, bisphenol, bisphenol A, bisphenol AP (1,1-bis(4-hydroxylphenyl)-1-phenyl ethane), bisphenol F, bisphenol K, tetrabromobisphenol A, phenol-formaldehyde novolac resins, alkyl substituted phenol-formaldehyde resins, phenol-hydroxybenzaldehyde resins, cresol-hydroxybenzaldehyde resins, dicyclopentadiene-phenol resins, dicyclopentadiene-substituted phenol resins tetramethylbiphenol, tetramethyl-tetrabromobiphenol, tetramethyltribromobiphenol, tetrachlorobisphenol A and any combination thereof.

Examples of diepoxides particularly useful in the present disclosure include diglcidyl ether of 2,2-bis(4-hydroxyphenyl) propane (generally referred to as bisphenol A) and diglycidyl ether of 2,2-bis(3,5-dibromo-4-hydroxyphenyl) propane (generally referred to as tetrabromobisphenol A).

Other useful polyepoxide resins which can be used in the practice of the present disclosure are cycloaliphatic epoxides. A cycloaliphatic epoxide consists of a saturated carbon ring having an epoxy oxygen bonded to two vicinal atoms in the carbon ring for example as illustrated by the following general formula:

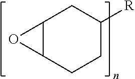

wherein R is as defined above and n is as defined above.

The cycloaliphatic epoxide may be a monoepoxide, a diepoxide, a polyepoxide, or a mixture of those. For example, any of the cycloaliphatic epoxides described in U.S. Pat. No. 3,686,359, incorporated herein by reference, may be used in the present disclosure. As an illustration, the cycloaliphatic epoxides that may be used in the present disclosure include, for example, (3,4-epoxycyclohexyl-methyl)-3,4-epoxy-cyclohexane carboxylate, bis-(3,4-epoxycyclohexyl) adipate, vinylcyclohexene monoxide and mixtures thereof.

In embodiments, the TIM composition includes one or more polyepoxide resins, such as mixture of polyepoxide resins. The polyepoxide resins can include conventional epoxy resin compounds. In general, the polyepoxide resin may be a single polyepoxide resin compound used alone or a mixture of two or more polyepoxide resins used in combination, that is, a curable polyepoxide resin composition which is cured to form the TIM composition of the present disclosure. Notably, the TIM composition includes at least one polyepoxide resin.

Non-limiting examples of suitable commercially available polyepoxide compounds may include those available from the Dow Chemical Company DER™ 300 series, DEN™ 400 series, DER™ 500 series, DER™ 600 series and epoxy series DER™ 700. For example, the polyepoxide resin may include DER 331 (bisphenol A diglycidyl ether), DER 354 (bisphenol F diglycidyl ether), DER 324 (diluent modified epoxy), DLVE 18 (A low viscosity epoxy resin blend) and other known epoxy resins and blends of the above known epoxy resins. DER330, DER331, DER332, DER354, DER324 and DLVE 18, DLVE 19, DLVE 52 are epoxy resins available from Olin Chemical Company.

In one embodiment, the polyepoxide resin includes a modified polyepoxide resin. For instance, the modified polyepoxide resin can include a polyepoxide resin modified with an ether, such as an aliphatic ether. In embodiments, the modified polyepoxide resin can be modified with a cycloaliphatic polyglicidyl ether.

The polyepoxide resin utilized in the present disclosure can have a viscosity of from about 350 mPas to about 550 mPas at a temperature of about 25° C., such as from about 375 mPas to about 525 mPas, such as from about 400 mPas to about 500 mPas.

In embodiments, the resin includes an acrylic resin. The acrylic resin useful in the practice of the present disclosure is suitably a triacrylate resin.

In embodiments, the resin includes a blend of epoxy and acrylic resins. In one embodiment, the resin includes a combination of polyepoxide and triacrylate resins. A non-limiting example of an embodiment including a polyepoxide and triacrylate resin blend includes DLVE52 and trimethylolpropane triacrylate.

The resin or combination of resins can be present in amounts ranging from about 1 wt. % to about 10 wt. %, such as from about 2 wt. % to about 9 wt. %, such as from about 3 wt. % to about 8 wt. %, such as from about 4 wt. % to about 7 wt. %, based on the total weight of the TIM composition.

c. Silane-Based Adhesion Promoter

In embodiments, the composition can include a silane-based adhesion promoter. The adhesion promoter includes compounds or polymers that can facilitate cross-linking and can be configured to function also as a surface modifier. As noted, the adhesion promoter includes a silane (e.g., an organosilane). The organosilane compound may, for example, be any alkoxysilane as is known in the art, such as vinlyalkoxysilanes, epoxyalkoxysilanes, aminoalkoxysilanes, mercaptoalkoxysilanes, and combinations thereof. In one embodiment, for instance, the organosilane compound may have the following general formula:

R⁵—Si—(R⁶)₃,
wherein, R5 is a sulfide group (e.g., —SH), an alkyl sulfide containing from 1 to 10 carbon atoms (e.g., mercaptopropyl, mercaptoethyl, mercaptobutyl, etc.), alkenyl sulfide containing from 2 to 10 carbon atoms, alkynyl sulfide containing from 2 to 10 carbon atoms, amino group (e.g., NH2), aminoalkyl containing from 1 to 10 carbon atoms (e.g., aminomethyl, aminoethyl, aminopropyl, aminobutyl, etc.); aminoalkenyl containing from 2 to 10 carbon atoms, aminoalkynyl containing from 2 to 10 carbon atoms, and so forth; and R6 is an alkoxy group of from 1 to 10 carbon atoms, such as methoxy, ethoxy, propoxy, and so forth.

Aminosilane compounds are particularly suitable and may include monomeric or oligomeric (<6 units) silanes. Aminotrialkoxysilanes may be employed in certain embodiments to form a three dimensional network of Si—O—Si covalent bonds at the surface and around the surface of the fibers. Aminodialkoxysilanes may likewise be employed in certain embodiments to form a hairlike structure on the surface of the fibers. While not necessarily forming a three-dimensional crosslinked protective sheath around the fibers, the dialkoxysilanes may nevertheless facilitate impregnation of the fiber bundles and wetting of the individual fibers by a polymer melt, as well as reduce the hydrophilicity of the surface of the fibers believed to contribute to resistance to hydrolysis. Thus, it may be desirable to employ trialkoxysilanes, dialkoxysilanes, or mixtures thereof in the sizing composition. Specific examples of suitable aminosilanes may include, for instance, aminodialkoxysilanes, such as γ-aminopropylmethyldiethoxysilane, N-β-(Aminoethyl)-gamma-aminopropylmethyldimethoxysilane, N-β-(Aminoethyl)-γ-aminopropyl-methyldimethoxysilane, N-β-(Aminoethyl)-γ-aminoisobutylmethyldimethoxy-silane, γ-aminopropylmethyldimethoxysilane, N-β-(Aminoethyl)-γ-aminopropyl-methyldiethoxysilane, etc.; aminotrialkoxysilanes, such as γ-aminopropyltriethoxysilane, γ-aminopropyltri-methoxysilane, N-β-(Aminoethyl)-Y-aminopropyl-trimethoxysilane, N-β-(Aminoethyl)-γ-aminopropyltriethoxysilane, diethylene-triaminopropyltrimethoxysilane, Bis-(γ-trimethoxysilylpropyl)amine, N-phenyl-γ-aminopropyltrimethoxysilane, γ-amino-3,3-dimethylbutyltrimethoxysilane, γ-aminobutyltriethoxysilane, etc.; as well as mixtures of any of the foregoing. The organosilanes can be bifunctional or multifunctional. The silane-based adhesion promoter can also include a triazine silane.

The silane-based adhesion promoter is present in the TIM composition in amounts ranging from about 0.01 wt. % to about less than 1 wt. %, such as from about 0.1 wt. % to about 0.8 wt. %, such as from about 0.2 wt. % to about 0.5 wt. %, based on the total weight of the TIM composition.

d. Rubber

The TIM composition includes a rubber component. As used herein, “rubber” refers to any elastomer or mixture thereof that is capable of being vulcanized (that is crosslinked or cured). The terms “elastomer” and “rubber” may be used interchangeably herein. Reference to a rubber or elastomer may include mixtures of more than one. Useful rubbers typically contain a degree of unsaturation in their polymeric main chain. Some non-limiting examples of these rubbers include polyolefin copolymer elastomers, butyl rubber, natural rubber, styrene-butadiene copolymer rubber (e.g., styrene/ethylene-butadiene/styrene), butadiene rubber, acrylonitrile rubber, halogenated rubber such as brominated and chlorinated isobutylene-isoprene copolymer rubber, butadiene-styrene-vinyl pyridine rubber, urethane rubber, polyisoprene rubber, epichlorohydrin terpolymer rubber, ethylene propylene diene monomer (EPDMP rubber, and polychloroprene).

In certain embodiments, the rubber includes a maleic anhydride-butadiene copolymer. In embodiments, the maleic anhydride-butadiene copolymer is a liquid at room temperature (e.g., 20° C. to 22° C.). The maleic anhydride-butadiene copolymer rubber can have a number average molecular weight of about 2,000 g/mol to about 8,000 g/mol, such as from about 2,000 g/mol to about 5,000 g/mol, such as from about 2,000 g/mol to about 3,500 g/mol. The maleic anhydride-butadiene copolymer used in the present disclosure may also be prepared according to various known techniques for example by the reaction of polybutadiene with maleic anhydride as described in U.S. Pat. Nos. 4,028,437; 4,601,944; and 5,300,569, incorporated herein by reference. A chemical structure formula of the maleic anhydride-butadiene is:

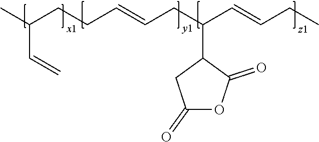

Wherein, the x₁, y₁, and z₁ are positive integers.

Commercially available suitable rubbers can include Ricon 184MA6: styrene-butadiene-maleic anhydride terpolymer, available from Cray Valley; Ricon 100: styrene-butadiene copolymer, available from Cray Valley; Ricon 257: styrene-butadiene-divinylbenzene terpolymer, available from Cray Valley; B-3000: polybutadiene, available from Nippon Soda Co., Ltd.; Ricon 130MA13: maleic anhydride-butadiene copolymer, available from Cray Valley; Ricon 131MA5: maleic anhydride-butadiene copolymer, available from Cray Valley. In embodiments, the rubber includes Ricon™ 130MA13, which is a maleic anhydride-butadiene copolymer with an average molecular weight Mn of 2,900 and an anhydride equivalent weight of 762 available from Cray Valley.

In other embodiments, the rubber can include vulcanizable elastomers including polyolefin copolymer elastomers. These copolymers are made from one or more of ethylene and higher alpha-olefins, which may include, but are not limited to propylene, 1-butene, 1-hexene, 4-methyl-1 pentene, 1-octene, 1-decene, or combinations thereof, and may include one or more copolymerizable, multiply unsaturated comonomer, such as diolefins, or diene monomers. The alpha-olefins can be propylene, 1-hexene, 1-octene, or combinations thereof. These rubbers may lack substantial crystallinity and can be suitably amorphous copolymers.

The diene monomers may include, but are not limited to, 5-ethylidene-2-norbornene; 1,4-hexadiene; 5-methylene-2-norbornene; 1,6-octadiene; 5-methyl-1,4-hexadiene; 3,7-dimethyl-1,6-octadiene; 1,3-cyclopentadiene; 1,4-cyclohexadiene; dicyclopentadiene; 5-vinyl-2-norbornene, divinyl benzene, and the like, or a combination thereof. The diene monomers can be 5-ethylidene-2-norbornene and/or 5-vinyl-2-norbornene. If the copolymer is prepared from ethylene, alpha-olefin, and diene monomers, the copolymer may be referred to as a terpolymer (EPDM rubber), or a tetrapolymer in the event that multiple alpha-olefins or dienes, or both, are used (EAODM rubber).

Elastomers that are polyolefin elastomer copolymers can contain, unless specified otherwise herein, from about 15 to about 90 mole percent ethylene units deriving from ethylene monomer, from about 40 to about 85 mole percent, or from about 50 to about 80 mole percent ethylene units. The copolymer may contain from about 10 to about 85 mole percent, or from about 15 to about 50 mole percent, or from about 20 to about 40 mole percent, alpha-olefin units deriving from alpha-olefin monomers. The foregoing mole percentages are based upon the total moles of the mer units of the polymer. Where the copolymer contains diene units, the copolymers may contain from 0.1 to about 14 weight percent, from about 0.2 to about 13 weight percent, or from about 1 to about 12 weight percent units deriving from diene monomer. The weight percent diene units deriving from diene may be determined according to ASTM D-6047. In some occurrences, the copolymers contain less than 5.5 weight percent, such as less than 5.0 weight percent, such as less than 4.5 weight percent, such as less than 4.0 weight percent units deriving from diene monomer. In yet other cases, the copolymers contain greater than 6.0 weight percent, such as greater than 6.2 weight percent, such as greater than 6.5 weight percent, such as greater than 7.0 weight percent units, such as greater than 8.0 weight percent deriving from diene monomer.

The polyolefin elastomer copolymer may be obtained using polymerization techniques known in the art such as traditional solution or slurry polymerization processes. For instance, the catalyst employed to polymerize the ethylene, alpha-olefin, and diene monomers into elastomeric copolymers can include both traditional Ziegler-Natta type catalyst systems, especially tubes including titanium and vanadium compounds, as well as metallocene catalysts for Group 3-6 (titanium, zirconium, and hafnium) metallocene catalysts, particularly the bridged mono- or biscyclopentadienyl metallocene catalysts. Other catalyst systems such as Brookhart catalyst systems may also be employed.

In one embodiment, the elastomer may include a butyl rubber. For instance, the butyl rubber includes copolymers and terpolymers of isobutylene and at least one other comonomer. Useful comonomers include isoprene, divinyl aromatic monomers, alkyl substituted vinyl aromatic monomers, and mixtures thereof. Exemplary divinyl aromatic monomers include vinyl styrene. Exemplary alkyl substituted vinyl aromatic monomers include α-methyl styrene and paramethyl styrene. These copolymers and terpolymers may also be halogenated such as in the case of chlorinated and brominated butyl rubber. In one or more embodiments, these halogenated polymers may derive from monomers such as parabromomethylstyrene.

In one or more embodiments, the butyl rubber includes copolymers of isobutylene and isoprene, copolymers of isobutylene and paramethyl styrene, terpolymers of isobutylene, isoprene, and divinyl styrene, branched butyl rubber, and brominated copolymers of isobutene and paramethylstyrene (yielding copolymers with parabromomethylstyrenyl mer units). These copolymers and terpolymers may be halogenated. Furthermore, butyl rubbers may be prepared by polymerization, using techniques known in the art such as at a low temperature in the presence of a Friedel-Crafts catalyst.

The rubber is present in amounts of from about 1 wt. % to about 5 wt. %, such as from about 2 wt. % to about 5 wt. %, such as from about 2 wt. % to about 4 wt. %, based on the total weight of the TIM composition.

e. Curing Agent

It is known in the preparation of polyepoxide resin-containing adhesives to incorporate a hardener also referred to as a “curing agent” or a “crosslinking agent” in order to facilitate the crosslinking of the polyepoxide resin composition to form a thermoset resin. Various curing agents for polyepoxide resins are generally known including amines (e.g., imidazole compounds), phenolics, anhydrides, carboxylic acids, mercaptans, and isocyanates. Polyepoxide resins can also homopolymerize by reacting with both nucleophilic and electrophilic species and such species can be utilized herein as a curing agent. Other curing agents can include cationic initiators.

In one embodiment, the curing agent includes one or more imidazole compounds. Examples of suitable imidazole compounds include triphenylphosphine compounds, amine compounds, and trihalogen borane compounds. Examples of the imidazole compound include 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 2-phenyl-4,5-dihydroxymethylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-phenylimidazo Lithium trimellitate, 2,4-diamino-6-[2′-methylimidazolyl-(1′)]-ethyl-s-triazine, 2,4-diamino-6-[2′-undecylimidazolyl-(1′)]-Ethyl-s-triazine, 2,4-diamidine-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenyl-4,5-dihydroxymethylimidazole, 2-phenyl-4-methyl-5-hydroxymethylimidazole, and combinations thereof. Examples of the triphenylphosphine compound include triphenylphosphine, tri(p-methylphenyl)phosphine, tri (nonylphenyl)phosphine, diphenyltolylphosphine, tetraphenylphosphonium bromide, methyltriphenylphosphonium, methyltriphenylphosphonium chloride, methoxymethyltriphenylphosphonium, and benzyltriphenylphosphonium chloride. The triphenylphosphine compound includes a compound having both a triphenylphosphine structure and a triphenylborane structure. Examples of such a compound include tetraphenylphosphonium tetraphenylborate, tetraphenylphosphonium tetra-p-triborate, benzyltriphenylphosphonium tetraphenylborate, triphenylphosphine triphenylborane, and combinations thereof. Examples of the amine compound include monoethanolamine trifluoroborate, dicyandiamide, and combinations thereof. Examples of the trihalogen borane compound include trichloroborane and boron trifluoride monoethylamine. Only one type of curing agent may be used, or two or more types (e.g., mixtures) thereof may be used.

In one embodiment, the curing agent includes 2-phenyl-4,5-dihydroxymethylimidazole, which is commercially available as CUREZOL 2PHZ-PW manufactured by Shikoku Kasei Kogyo Co., Ltd.

In one embodiment, the curing agent includes bisphenol A diglycidyl ether/2-ethyl-4-methylimidazole adduct, which is commercially available as CUREDUCT P-0505 manufactured by Shikoku Chemicals Co. Ltd. in combination with a stabilizer such as an epoxy-phenol-borate mixture which is commercially available as CUREDUCT L-07N manufactured by Shikoku Chemicals Co., Ltd.

The curing agent or combination of curing agents can be present in amounts of from about 0.02 wt. % to about 1 wt. %, such as from about 0.02 wt. % to about 0.8 wt. %, such as from about 0.04 wt. % to about 0.7 wt. %, such as from about 0.06 wt. % to about 0.2 wt. % based on the total weight of the TIM composition.

f. Composition Properties
i. Resistivity

The TIM composition once cured can have a resistivity ranging from about 30 μOhm/cm to about 70 μOhm/cm, such as from about 40 μOhm/cm to about 60 μOhm/cm, such as from about 45 μOhm/cm to about 65 μOhm/cm. Resistivity of the cured TIM composition of the present disclosure can be measured according to the following four probe resistivity measurement set-up. The TIM composition is disposed (e.g., printed) on a cover (e.g., a metal cover such as nickel or copper) in a square pattern. Each square has a length and width of 3 mm×3 mm. The applied TIM composition for each square has a thickness ranging from about 30 μm to about 40 μm. The resistivity is measured at a temperature ranging from about 20° C. to 22° C. (e.g., room temperature). The resistivity was measured with a four point probe system. The four point probe system can include a linear four point probe. The linear four point probe system can include two outer probes and two inner probes. The outer probes flow current into the material tested and the inner probes measure the voltage drop. From this data, the resistivity of the material can be determined. However, the resistivity can be determined in accordance with known four point probe systems including linear four point probes or other four point probe configurations as would be known by those of skill in the art.

ii. Thermal Conductivity

The TIM composition once cure can have a thermal conductivity ranging from about 8 W/mK to about 30 W/mK, such as from about 10 W/mK to about 25 W/mK, such as from about 15 W/mK to about 20 W/mK. Thermal conductivity of the TIM composition of the present disclosure can be measured according to the following method. The Transient Plane Source (TPS) method (aka., Hot Disk method), was utilized and provides information on the thermal conductivity, thermal diffusivity and specific heat per unit volume of the material in accordance with ISO 22007-2. To test, a specimen containing an embedded hot disc probe of negligible heat capacity is allowed to equilibrate at a given temperature. A heat pulse in the form of a stepwise function is produced by an electrical current through the probe to generate a dynamic temperature field within the specimen. The increase in the temperature of the probe is measured as a function of time. Equipment use includes a Hot Disk TPS 3500.

iii. Viscosity

The TIM composition can have a viscosity ranging from about 90 Pas to about 150 Pas, such as from abut 100 Pas to about 140 Pas, such as from about 110 Pas to about 130 Pas measured with a Brookfield DVE SC 2HA SC4-14 set at 10 RPM measured at temperatures ranging from about 20° C. to about 30° C. In other embodiments, the TIM composition has a viscosity ranging from about 60 Pas to about 90 Pas, such as from about 70 Pas to about 80 Pas, such as from about 65 Pas to about 85 Pas, when measured with a Brookfield DVE SC 2HA SC4-14 set at 50 RPM measured at temperatures ranging from about 20° C. to about 30° C. The TIM composition can have a thixotropic index ranging from about 1.9 to about 3.2, such as from about 2 to about 3, such as from about 2.5 to about 3. Here, the thixotropic index means a ratio of the viscosity of the TIM composition at a shear rate of 10 rpm to the viscosity of the TIM composition at a shear rate of 50 rpm as measured with a Brookfield DVE SC 2HA SC4-14 at room temperature (e.g., 20-23° C.).

g. Solvent-Free

Further, the TIM composition can be substantially free from solvent. For instance, no additional solvents or dispersants are necessary to modify the viscosity of the TIM composition and the TIM composition includes components that are either dispersible or miscible within the blend of the polyepoxide resin, adhesion promoter, and rubber.

### II. Articles

The TIM composition can be applied to one or more components (e.g., covers and semiconductor chips) and cured to bond the components together. The TIM composition can be utilized in a wide array of applications (e.g., electronic articles, such as semiconductors etc.) where an electrical connection is required between component parts, such as between a cover (e.g., printed circuit board) and a semiconductor chip.

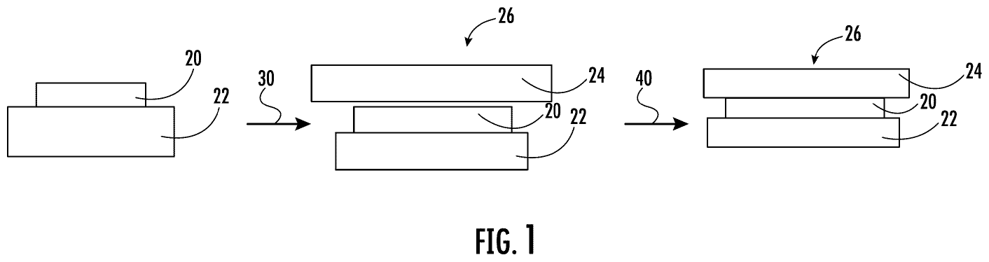

For instance, as shown in FIG. 1, the TIM composition 20 can be applied to a cover 22. In embodiments, the cover 22 can be further thermally connected to a substrate (not shown). The cover 22 can include a heat sink or heat spreader and can be formed from various materials. In embodiments, the cover 22 can be formed from conductive materials. The cover 22 can also include other types of materials such as dielectric materials and/or semiconductor materials. In embodiments, the cover 22 is formed from a transition metal, such as nickel, copper, and mixtures thereof. In other embodiments, the cover 22 can be formed from post-transition metals, such as aluminum. For instance, in embodiments, the surface of the cover 22 in contact with the TIM composition can include a nickel-plated copper component. In other embodiments, the surface of the cover 22 in contact with the TIM composition can include a nickel-plated aluminum component. At 30, a semiconductor chip 24 is placed on the TIM composition 20 forming a component assembly 26 (e.g., semiconductor device). The semiconductor chip 24 can be formed from any suitable material including conductive materials, dielectric materials, semiconductor materials, etc. In embodiments, the semiconductor chip 24 is formed from silicon, silicon germanium, silicon oxide, silicon nitride, or combinations thereof. At 40, the component assembly 26 is cured to set the TIM composition 20 thereby thermally bonding the cover 22 to the semiconductor chip 24.

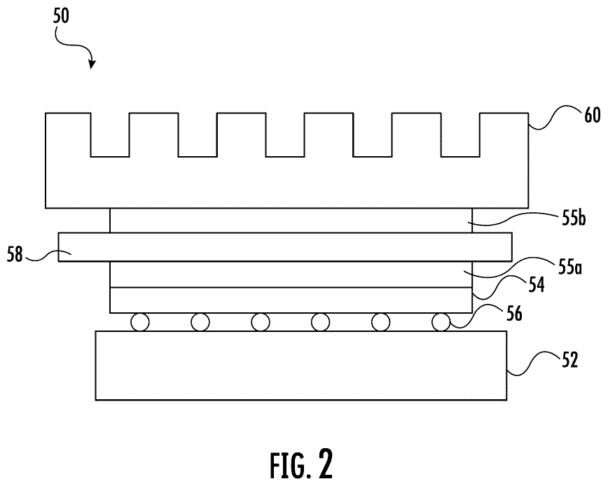

As illustrated in FIG. 2, in other embodiments, an electronic component 50 is illustrated utilizing two layers of TIM composition. Electronic component 50 includes a substrate 52 that is attached to a silicon die 54 via interconnects 56. The silicon die 54 generates heat that is transferred through a first TIM composition 55a that is adjacent to at least one side of the silicon die 54. A heat spreader 58 is positioned adjacent to the first TIM composition 55a and acts to dissipate a portion of the heat that passes through the first TIM composition 55a. A heat sink 60 is positioned adjacent to the heat spreader 58 to dissipate any transferred thermal energy. Optionally, as shown, a second TIM composition 55b is disposed between the heat spreader 58 and the heat sink 60. However, in embodiments, it should be appreciated that the heat sink 60 can be disposed directly on the heat spreader 58 without the use of an additional layer of TIM composition (not shown). In embodiments, the second TIM composition 55b can have a thickness that is greater than the thickness of the first TIM composition 55a.

### III. Methods

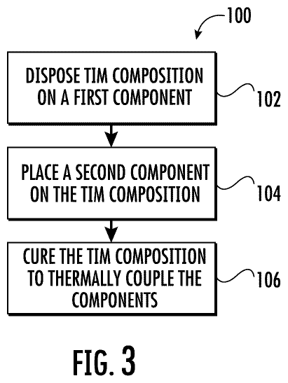

FIG. 3 depicts a flow diagram of one example method of forming a device according to the present disclosure. In some embodiments, the method (100) can include a method for thermally connecting a semiconductor chip to a heat spreader or heat sink.

At (102), the method includes disposing (e.g., dispensing) a TIM composition on a first component (e.g., a cover). The TIM composition can include the components described hereinabove. For instance, the TIM composition can include conductive material dispersed in a resin with a silane-based adhesion promoter. The TIM composition can also include rubber and a curing agent. The TIM composition can be disposed on a suitable cover formed from a conductive material (e.g., heat sink, cold plate, or heat spreader). The first component can be made from a metal or contain metal components thereon. The first component can include a metal material such as a transition metal. Suitable transition metals include row 4 transition metals. In embodiments, the transition metal comprises nickel, copper, alloys thereof, and combinations thereof. For instance, in embodiments, the first component comprises a nickel-plated copper component. In such an embodiment, the nickel surface is in contact with and, after curing, bonded to the TIM composition. The first component can be a heat sink, cold plate, or heat spreader or any component for removing thermal energy from the second component (e.g., semiconductor chip).

The TIM composition is applied to the first component in such manner to provide a TIM composition coating having a substantially uniform coating thickness. Thickness uniformity can decrease warpage of the TIM composition during curing, which can decrease bending or distortion of the resulting component assembly due to the differences in the coefficient of thermal expansion between the TIM composition and the components.

To make the TIM composition, the components can be mixed together, and roll milled. In one embodiment, to make the TIM composition the mixing is as follows: (1) the rubber is mixed with the resin, (2) the silane-based adhesion promoter is added and mixed with the blended rubber and resin, (3) the conductive material (e.g., metal powders) is added to the blend of rubber, resin, and silane-based adhesion promoter and mixed, (4) lastly, the catalyst is added. Notably, in embodiments, the catalyst should be added last and can be added once the conductive adhesive mixture is ready to be roll milled. The composition can be mixed with a Thinky™ mixer at an RPM ranging from about 500 rpm to about 1,500 rpm, such as about 1,000 rpm. The mixture can be mixed for a time period of about 10 seconds to about 1 minute, such as from about 20 seconds to about 50 seconds, such as from about 30 seconds to about 40 second. The mixture can then be roll milled by any suitable process until a desired Fineness of Grind (FOG) is obtained. The FOG can be about 5/2 or below. The FOG can be determined using a Hegman gauge according to known methods. The resulting TIM composition can be stored in the freezer at temperatures under 0° C., such as about −25° C., such as about −60° C. until used.

At (104), the method includes disposing a second component on the TIM composition to form a component assembly. The second component can include a semiconductor chip or another heat generating element. The second component can be formed from any suitable material including dielectric or semiconductive materials. For instance, the second component can be formed from silicon, silicon dioxide, silicon nitride, silicon germanium, or combinations thereof.

At (106), the TIM composition is cured to bond the first component and the second component. For instance, the TIM composition can be cured by heating the composition or by chemically curing the composition. In embodiments, the TIM composition is heated to a curing temperature of from about 100° C. to about 400° C., such as from about 150° C. to about 350° C., such as from about 125° C. to about 180° C. The TIM composition can be heated for a time period ranging from about 5 minutes to about 1 hour, from about 10 minutes to about 50 minutes, from about 15 minutes to about 45 minutes, from about 20 minutes to about 40 minutes, and/or about 30 minutes. In embodiments, the heating time is about 10 minutes. The heating can be completed in any suitable oven or heater. After heating, the component assembly is both thermally coupled and bonded by the TIM composition. For instance, in embodiments the surface of a semiconductor chip is bonded via the cured TIM composition to a surface of a heat sink, cold plate, or a heat spreader. Thus, heat generated during operation of the semiconductor chip is thermally transferred by the TIM composition to the heat sink, cold plate, or heat spreader and removed from the semiconductor chip.

### Definitions

As used herein, ranges and amounts can be expressed as “about” a particular value or range. “About” is intended to also include the exact amount. Hence “about 5 percent” means “about 5 percent” and also “5 percent.” “About” means within typical experimental error for the application or purpose intended.

As used herein, “optional” or “optionally” means that the subsequently described event or circumstance does or does not occur, and that the description includes instances where said event or circumstance occurs and instances where it does not. For example, an optional component in a method or composition means that the component may be present or may not be present in the method or composition.

As used herein, the term “substantially free” means no more than an insignificant trace amount present and encompasses completely free (e.g., 0 molar % up to 0.01 molar %).

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

All references to singular characteristics or limitations of the present disclosure shall include the corresponding plural characteristic or limitation, and vice versa, unless otherwise specified or clearly implied to the contrary by the context in which the reference is made.

The methods and compositions of the present disclosure, including components thereof, can comprise, consist of, or consist essentially of the essential elements and limitations of the disclosure described herein.

These and other modifications and variations of the present disclosure may be practiced by those of ordinary skill in the art, without departing from the spirit and scope of the present disclosure. In addition, it should be understood that aspects of the various embodiments may be interchanged both in whole or in part. Furthermore, those of ordinary skill in the art will appreciate that the foregoing description is by way of example only and is not intended to limit the disclosure so further described in such appended claims.

What is claimed is:

1. A semiconductor device, comprising;
a semiconductor chip formed from a semiconductive material and a cover formed from a conductive material bonded with a thermal interface material composition comprising a conductive material comprising metal particles dispersed in a resin and a silane-based adhesion promoter.

2. The semiconductor device of claim 1, wherein the metal particles comprise silver.

3. The semiconductor device of claim 1, wherein the metal particles are in the form of flakes having a D50 of from about 1 μm to about 4 μm.

4. The semiconductor device of claim 1, wherein the conductive material further comprises submicron metal particles.

5. The semiconductor device of claim 4, wherein the submicron metal particles comprise a D50 of from about 0.1 μm to about 0.7 μm.

6. The semiconductor device of claim 4, wherein the submicron metal particles comprise silver.

7. The semiconductor device of claim 4, wherein the submicron metal particles are present in an amount of from about 0.1 wt. % to about 10 wt. % based on the total weight of the composition.

8. The semiconductor device of claim 1, wherein the metal particles are present in an amount of from about 85 wt. % to about 95 wt. % based on the total weight of the thermal interface material composition.

9. The semiconductor device of claim 1, wherein the resin comprises a polyepoxide resin, a triacrylate resin, or combinations thereof.

10. The semiconductor device of claim 1, wherein the resin is present in an amount ranging from 1 wt. % to about 10 wt. %.

11. The semiconductor device of claim 1, wherein the silane-based adhesion promoter comprises a bifunctional organosilane.

12. The semiconductor device of claim 1, wherein the silane-based adhesion promoter is present in an amount of from about 0.01 wt. % to about 1 wt. % based on the total weight of the thermal interface material composition.

13. The semiconductor device of claim 1, wherein the thermal interface material composition further comprises a rubber.

14. The semiconductor device of claim 13, wherein the rubber comprises vinyl butadiene rubber.

15. The semiconductor device of claim 14, wherein the vinyl butadiene rubber has a number average molecular weight of from about 3,000 to about 3,500 g/mol.

16. The semiconductor device of claim 1, wherein the thermal interface material composition further comprises a curing agent.

17. The semiconductor device of claim 16, wherein the curing agent is present in an amount of from about 0.02 wt. % to about 0.25 wt. % based on the total weight of the thermal interface material composition.

18. The semiconductor device of claim 16, wherein the curing agent comprises an imidazole compound.

19. The semiconductor device of claim 1, wherein the thermal interface material composition has a resistivity of from about 30 μOhm/cm to about 70 μOhm/cm or a thermal conductivity ranging from about 8 W/mK to about 30 W/mK.

20. A method for making a semiconductor device, the method comprising:
disposing a thermal interface material composition comprising a conductive material comprising metal particles dispersed in a resin and a silane-based adhesion promoter on a cover formed from a conductive material;
placing a semiconductor chip formed from a semiconductive material on the thermal interface material composition forming a component assembly; and
curing the component assembly to bond the cover and the semiconductor chip.
